(19) United States
(12) Patent Application Publication
(10) Pub. No.: US 2012/0104287 A1
(43) Pub. Date: May 3, 2012

(54) LOCATING BADGE

(76) Inventors: Harry G. Derks, Holland, MI (US); Donald W. Beery, Hudsonville, MI (US)

(21) Appl. No.: 12/917,226

(22) Filed: Nov. 1, 2010

(51) Int. Cl. G21K 5/02; H05K 5/02; G06K 19/06

(52) U.S. Cl. 250/493.1; 235/494; 312/223.1

(57) ABSTRACT

A locating badge comprising a housing containing an opaque medium and an IR transmitting device. At least a portion of the housing is transparent to visible light and a portion to IR, and the housing preferably comprises two releasably mechanically engageable housing members. The opaque medium, viewable through the transparent portion of the housing, may be an elastomeric membrane, which also provides water resistance by sealing the seam between housing members. Additional functionality may be provided by inserting identification materials within the housing (also viewable through the transparent portion of the housing) or by providing an opening in the housing allowing access to a membrane button, wherein the elastomeric membrane functions as the cover for the button and as a sealing gasket around the opening in the housing. The badges described herein can easily be used in a color-coded system, by changing the opaque medium inside the badge.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO SEQUENCE LISTING, A TABLE OR A COMPUTER PROGRAM LISTING COMPACT DISC APPENDIX

Not applicable.

### BACKGROUND OF THE INVENTION

The invention is in the field of identification and locator badges.

### BRIEF SUMMARY OF THE INVENTION

The invention comprises a locating badge having a housing, an opaque, preferably colored medium, and a transmitting device. At least a portion of the housing is transparent to visible light and at least a portion of the housing is transparent to IR. The housing is also capable of being opened to access the interior, and re-closed via a releasably mechanically engageable feature, preferably a feature such as a snap-lock feature, around at least a portion of the perimeter of at least one housing member. Preferably, the housing comprises at least two housing members, at least one of which is transparent to both visible light and IR.

The opaque medium is disposed within the housing, such that it is visible through the portion of the housing which is transparent to visible light. Preferably, the opaque medium comprises an elastomeric membrane which extends into the area adjacent to the mechanically engageable features, sealing such features to render the housing water resistant. Where “opaque” is used herein, it is intended to cover items with varying levels of opacity, whether the items are semi-transparent or completely opaque.

The transmitting device is situated inside the housing, and oriented such that the IR or visible light transmitted by the device, as applicable, are passed through the transparent portion of the housing.

Optionally, the locating badge incorporating the elastomeric membrane may be provided with additional functionality by the inclusion of a button without sacrificing the water-resistance provided by the elastomeric membrane, because the elastomeric membrane functions as a membrane with an integral electrical contact for a membrane button and also forms a gasket seal around the perimeter of the opening in the housing that is provided to allow access to the button.

### BRIEF DESCRIPTION OF THE DRAWINGS

FIG. 1 is a front perspective view of the locating badge with a solid opaque membrane and a button.

FIG. 2 is a detail view of a cross section of the locating badge, showing the snap lock feature and membrane placement and the button;

FIG. 3 is a front view of the locating badge being used as a picture identification;

FIG. 4 is a front view of the locating badge being used as a name tag; and

FIG. 5 is a front view of the locating badge incorporating the use of a bar code on the badge.

### DETAILED DESCRIPTION OF THE PREFERRED EMBODIMENTS

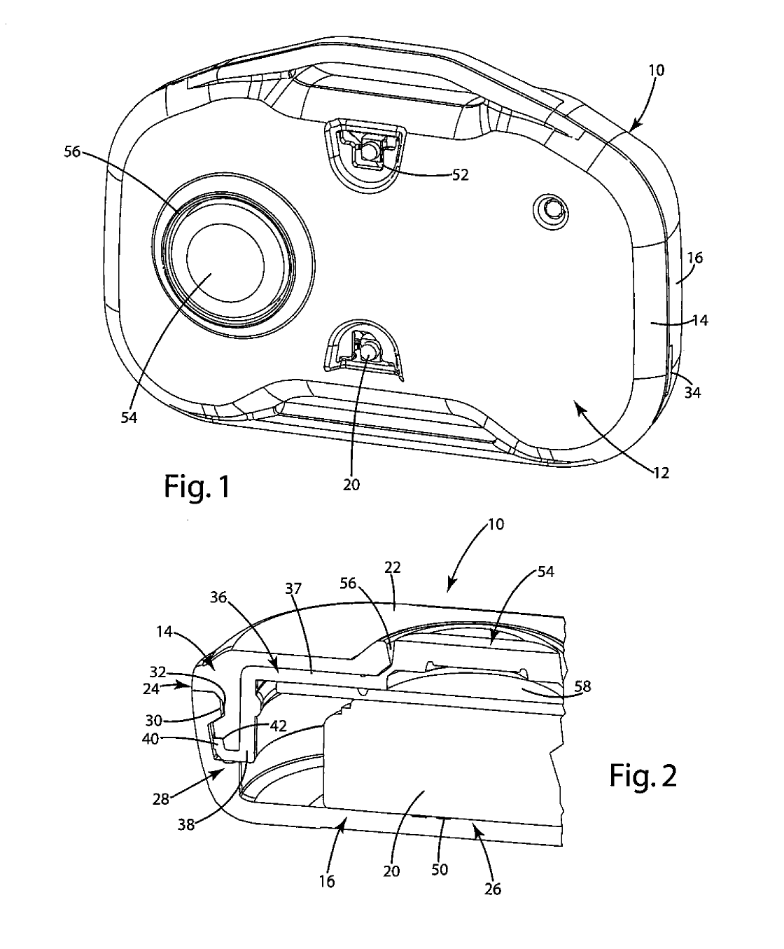

One preferred embodiment of the badge 10 as described herein comprises a housing 12, with at least two housing members 14, 16, an opaque member 36, 60 and functional electronic components 20 such as an Infrared (“IR”) or visible light signal transmitter. (FIG. 1) The badge 10 as described herein is suitable for use as a real-time locating badge, capable of sending and receiving electromagnetic signals, including, without limitation, IR signals or RF signals from electrical components inside the housing 12. The badge 10 can be used to locate people, inventory, animals or other objects that may move or may be moved throughout a space. As further described below, the badge 10 can also be changeably color coded, or provided with human-readable, machine readable, or other optically-readable identification forms, permitting use as a standard identification badge in addition to locating badge functionality.

With respect to housing 12, at least a portion of housing 12 is transparent to IR signals and at least a portion of housing 12 is transparent to visible light. Preferably, housing 12 comprises a first housing member 14 and a second housing member 16, with first housing member 14, which defines the front of housing 12, being transparent to IR and visible light. Housing 12 may be made from any materials meeting the above requirements, but is preferably a sturdy, light-weight, durable material to withstand use as an ID and/or locating badge for people or materials in varied environments and conditions. The material is also preferably ductile and elastic enough to avoid breaking or cracking upon frequent handling and potential opening and closing. Certain examples of preferable housing materials include ABS, acrylic, polycarbonate or other materials. Housing 12 may be shaped to be wearable by a person, or to be attached to inventory or goods in any known manner.

Preferably, first housing member 14 comprises a generally rectangular transparent front surface 22 and four side walls 24 extending backwards from the front surface 22 defining an open plane therebetween and second housing member 16 comprises a generally rectangular back surface 26 and four side walls 28 extending forward from the back surface 26 (FIG. 2). Other shapes, such as squares, circles, ovals, polygons or any other shape can be used instead of the generally rectangular front and back surfaces 22, 26 described in this embodiment.

Side walls 24 of first member 14 and side walls 28 of second member 16 are preferably engageable with each other via a “snap-lock” engagement. (FIG. 2) In one embodiment of such snap lock engagement, portions of side walls 24 extending a short distance from the edge thereof, are disposed interiorly to side walls 28 when first and second housing members 14, 16 are engaged. Side walls 24, 28 have generally aligned outer surfaces when first and second housing members 14, 16 are engaged. Side walls 28 of second housing member 16 have a ridge 30 extending towards the interior of housing 12 at the distal edge from back surface 26. Side walls 24 of first member 14 have an indentation 32, which is complementary to three sides of ridge 30, and, when engaged with second member 16, side walls 24 of first housing member 22 extend beyond ridge 30 toward the back surface 26. The end of side walls 28 of second member 16 may also have a notch 34 to allow the user of badge 10 to grip second housing member 16 to disengage the first and second housing members 14, 16 or to allow the insertion of a tool or other implement into the notch 34 to disengage the first and second housing members 14, 16. (FIG. 1).

It is contemplated that the snap-lock engagement would not be required to extend around the entire perimeter of badge 10. For example, one side of the perimeter could incorporate a hinge between first and second housing members 14, 16, with the remaining portion of the perimeter engageable via a snap lock feature.

Alternatively, or in addition to the snap lock functionality, a security screw or other security feature can be used on the housing, to inhibit unauthorized access to the interior of housing 12. This type of security feature may be desired when the badge 10 incorporates identification information in addition to the locating function.

In the preferred embodiment, an elastomeric membrane 36 is provided between first and second housing members 14, 16. Elastomeric membrane 36 is shaped to fit within the interior contours of the front surface 22, with a front wall 37 located against transparent front wall 22 of front housing member 14, and edges 38 extending toward back surface 26 and then radially outward into the space between side walls 24 of first member 14 and the interior of back surface 26 or a shaped portion of side wall 28 of second member 16. Elastomeric membrane 36 is preferably compressed between the distal end of side walls 24 of first member 14 and the interior of back surface 26 or a shaped portion of side wall 28 of second member 16. Elastomeric membrane 36 may optionally have a thicker bead 40 around its edge 38, and first and second members 14, 16 may have shaped notches or grooves 42 shaped to receive bead 40, to assist in retaining elastomeric membrane 36 between them to provide moisture resistance.

The back side of elastomeric membrane 36 and the interior side of back surface 26 define a cavity in the housing 12 wherein the functional electronic components 20, such as the IR transmitter can be housed. To provide a location to anchor IR signal transmitter 20, interior housing notches or other shaped features 50 may be provided to stabilize or mechanically engage electronic components 20. (FIG. 2) For example, electronic components 20 necessary or desirable to operate an IR locating system, an RF locating system, a combined IR/RF locating system or any other wireless locating system may be disposed between elastomeric membrane 36 and back surface 26. To maintain IR signal-sending functionality for an electronic component 20 placed behind elastomeric membrane 36, an opening 52 may be provided in front wall 37 of elastomeric membrane 36 through which the IR signal can be transmitted. Because the front wall 22 of housing 14 is transparent, the IR signal passing through opening 52 passes readily through front wall 22 without the need for an opening in the front wall 22.

The snap lock engagement, when combined with elastomeric membrane 36, renders housing 12 largely water resistant, and therefore more durable for use in certain environments where splashes or certain amounts of liquids or fluids may be encountered. The mechanical engagement may also permit housing 12 to be opened and assembled by an operator without the use of specialized tools, if desired.

Elastomeric membrane 36 is preferably semi-transparent or opaque, and may be provided in multiple colors to fit a particular housing 12, so that the locating badge 10 (due to the visibly transparent portions of housing 12) can be color-coded, and the color of a particular badge 10 can be altered, even in the field, by opening housing 12, changing elastomeric membrane 36, and closing housing 12, all preferably achievable without the use of specialized tools.

Additionally, one or more buttons 54 may be provided on badge 10. Buttons 54 may be formed by providing an opening 56 in housing 12, and locating a membrane button component 58 below opening 56 and behind elastomeric membrane 36, and embossing or otherwise providing integrated electrical contacts on the back side of the elastomeric membrane 36, such that when button 54 is depressed, the electrical contacts on the back side of elastomeric membrane 36 are forced into contact with membrane button component 58. (FIG. 2) Elastomeric membrane 36 then functions as a sealing gasket around the perimeter of opening 56, such that badge 10 retains its water resistance characteristics, even with one or more buttons 54.

For water resistance, particularly when a button 54 is not provided on badge 10, the sealing portion of elastomeric membrane 36 may be all that is required.

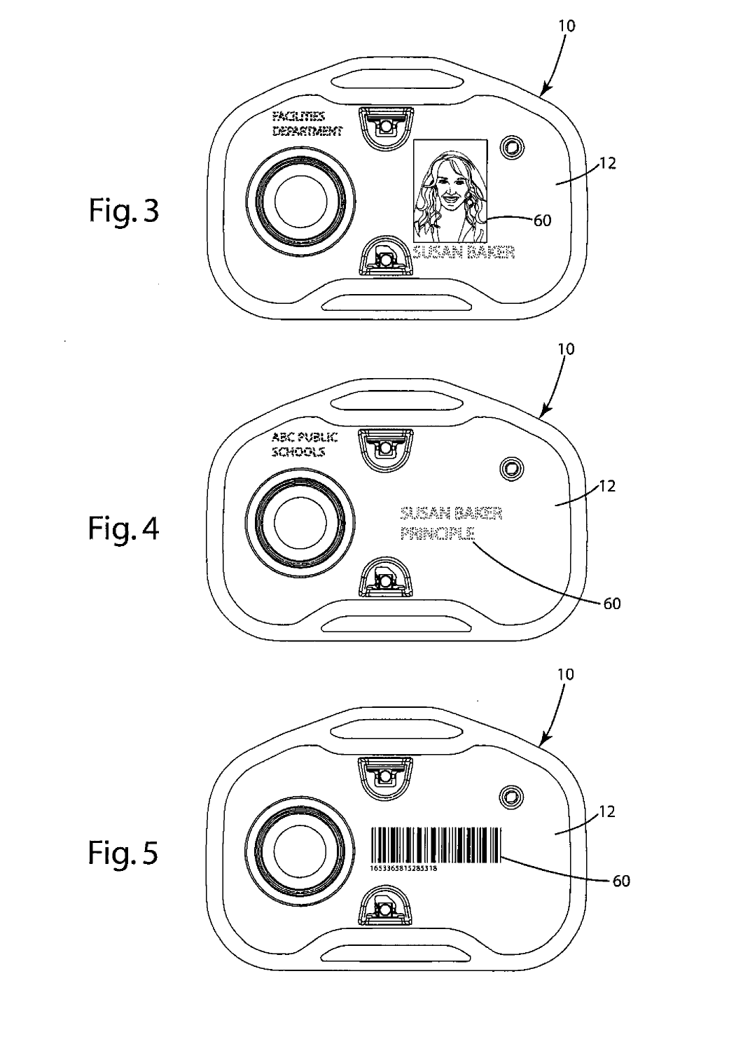

Further identification functionality may be provided for badge 10 by inserting an identification means 60 between elastomeric membrane 36 and the back side of front surface 22, by attaching an identification means 60 to the front side of front surface 22, or by printing identification means 60 on the surface of elastomeric membrane 36, or using any other method of printing, embossing, stamping or marking identification means 60 such that identification means 60 is visible through the portion of housing 12 which is transparent to visible light. (FIGS. 3-5).

Since elastomeric membrane 36 or any other opaque material such as identification means 60, are visible through the transparent front wall 22 of housing 12, and housing 12 can be opened and resealed without damage, locating badges 10 can easily be color-coded or display other information from a protected location within housing 12, and the color or information displayed by a particular badge 10 can be changed or modified without purchasing a replacement badge 10 or replacing any of the electronic components 48 therein.

Of course it is understood that the above is a description of preferred embodiments, and that various changes and alterations can be made to badge 10 without departing from the spirit and broader aspects of the invention.

What is claimed is:

1. A locating badge, comprising:
a housing, wherein at least a portion of the housing is transparent to visible light, at least a portion of the housing is transparent to IR radiation; and wherein the housing comprises at least a first member and a second member, whereby said housing is capable of being opened to access the interior and re-closed via a releasable mechanical engagement along at least a portion of the perimeter of at least one of the housing members;
an opaque medium disposed within the housing, wherein the opaque medium is visible through the portion of the housing which is transparent to visible light; and
a transmitting device situated inside the housing, wherein the transmitting device is capable of transmitting IR electromagnetic waves through the housing.

2. The locating badge of claim 1, wherein the first and second housing members can be separated from one another.

3. The locating badge of claim 2, wherein at least one of the first and second housing members is transparent to both IR and visible light.

4. The locating badge of claim 2, wherein the mechanical engagement between the first and second housing members is accomplished via an interengageable snap-lock feature around at least a portion of the perimeter edges of the housing members and wherein the housing members can be engaged and disengaged with each other via the snap-lock feature.

5. The locating badge of claim 4, wherein the interengageable snap-lock feature is operable without the use of specialized tools.

6. The locating badge of claim 1, wherein the opaque medium has an opening therein, thereby allowing transmission of visible light from behind the opaque medium through the housing.

7. The locating badge of claim 6, wherein the first housing member is transparent to visible light and IR.

8. The locating badge of claim 1, wherein the first housing member comprises a generally flat front surface and walls extending back therefrom around the perimeter of the front surface; the second housing member comprises a generally flat back surface and walls extending forward therefrom around the perimeter of the back surface; and the first housing member and the second housing member are interengageable via complementary snap-lock features provided around the perimeter of the walls of the first member and the walls of the second member.

9. The locating badge of claim 8, wherein the first housing member is transparent to visible light and IR.

10. The locating badge of claim 1, wherein the opaque medium is an elastomeric membrane.

11. The locating badge of claim 10, wherein the housing comprises a first housing member and a second housing member, and wherein the first housing member comprises a generally flat front surface and walls extending back therefrom around the perimeter of the front surface; the second housing member comprises a generally flat back surface and walls extending forward therefrom around the perimeter of the back surface; and the first housing member and the second housing member are mechanically engageable via complementary snap-lock features provided around the perimeter of the walls of the first member and the walls of the second member.

12. The locating badge of claim 10, wherein the elastomeric membrane extends inside the housing across the interior side of the front surface.

13. The locating badge of claim 12, wherein the front surface of the first housing is transparent to IR radiation, and the elastomeric membrane has an opening therein located adjacent the transparent front surface of said first housing, thereby allowing transmission of IR radiation from behind the elastomeric membrane through the housing.

14. The locating badge of claim 12, wherein the elastomeric membrane extends into the area adjacent to the snap-lock feature, thereby forming a water-resistant seal between the first housing member and the second housing member.

15. The locating badge of claim 14, wherein the elastomeric membrane has a bead around its perimeter; the side wall of the housing member which is disposed interiorly to the other side wall when the housing members are engaged has a notch around its perimeter; and the bead is disposed between the notch and the interior of the other housing member's side wall.

16. The locating badge of claim 10, wherein at least one button is provided.

17. The locating badge of claim 16, wherein the at least one button comprises a membrane button covered by the elastomeric membrane and wherein the at least one button is accessible through an opening in the housing.

18. The locating badge of claim 17, wherein the housing comprises a first housing member comprising a generally flat front surface and walls extending back therefrom around the perimeter of the front surface; a second housing member comprising a generally flat back surface and walls extending forward therefrom around the perimeter of the back surface; and the first housing member and the second housing member are mechanically engageable via complementary snap-lock features provided around the perimeter of the walls of the first member and the walls of the second housing member such that the distal end of the side walls of the first housing member are disposed interiorly to the side walls of the second housing member; wherein the walls of the first housing member have a notch around their perimeter; wherein the elastomeric membrane has a bead around its perimeter, and wherein the bead is disposed between the notch and back surface, such that the elastomeric membrane functions as a sealing gasket around the opening.

19. The locating badge of claim 11, wherein at least one button comprising a membrane button covered by the elastomeric membrane is accessible through an opening in the housing.

20. The locating badge of claim 19, wherein a rigid interior structure is provided inside the housing, forcing the elastomeric membrane into close proximity with the interior of the housing adjacent to the opening for the at least one button such that the elastomeric membrane functions as a sealing gasket around the opening.

21. The locating badge of claim 1, further comprising identification symbols provided on the opaque medium so as to be viewable through the portion of the housing transparent to visible light.

22. The locating badge of claim 21, wherein the identification symbol comprises an element chosen from the group consisting of a photograph, characters, graphics, a barcode, and any combination thereof.

23. The locating badge of claim 1, further comprising a medium provided with identification symbols disposed between the elastomeric membrane and the portion of the housing transparent to visible light.

24. The locating badge of claim 23, wherein the identification symbol comprises an element chosen from the group consisting of a photograph, characters, graphics, a barcode, and any combination thereof.

25. The locating badge of claim 1, further comprising identification symbols disposed on the housing.

26. The locating badge of claim 25, wherein the identification symbol comprises an element chosen from the group consisting of a photograph, characters, graphics, a barcode and any combination thereof.

27. The locating badge of claim 10, wherein the elastomeric membrane is colored.

28. A locating badge system, comprising:
at least a first badge as described in claim 27, with the elastomeric membrane being a first color;
at least a second badge as described in claim 27, with the elastomeric membrane being a second color;
wherein the first color and the second color are visible through the portion of the housing transparent to visible light, and so that a user can distinguish between the first badge and the second badge based on the color of the elastomeric membrane.

29. A method of using a locating badge as described in claim 1 to track an object, comprising the steps of:
affixing a locating badge to the object to be tracked by a locating system, wherein the locating system incorporates the use of IR signals to determine the location of locating badges.

30. A method of using the locating badge as described in claim 29, further comprising the step of selecting a badge with a desired color, wherein the desired color is based on a characteristic of the entity to be tracked.

31. A method of using the locating badge as described in claim 30, further comprising the steps of:
inserting an opaque medium of the desired color into the housing of the badge; and
closing the housing of the badge.

32. A method of using the locating badge as described in claim 29, wherein the opaque medium of the locating badge is printed with an identification symbol.

33. A method of using the locating badge as described in claim 29, wherein a medium with an identification symbol thereon is incorporated between the opaque medium and the housing.

34. A kit for assembling a locating badge comprising:
a housing, wherein at least a portion of the housing is transparent to visible light, at least a portion of the housing is transparent to IR radiation; and wherein the housing comprises at least a first member and a second member, whereby said housing is capable of being opened to access the interior and re-closed via releasable mechanical engagement along at least a portion of the perimeter of at least one of the housing members;
an opaque medium capable of being disposed within the housing, wherein the opaque medium is visible through the portion of the housing which is transparent to visible light;
wherein the housing is adapted to house an IR-transmitting device.

35. A kit for assembling a locating badge comprising:
a housing, wherein at least a portion of the housing is transparent to visible light, at least a portion of the housing is transparent to IR radiation; and wherein the housing comprises at least a first member and a second member, whereby said housing is capable of being opened to access the interior and re-closed via releasable mechanical engagement along at least a portion of the perimeter of at least one of the housing members;
an elastomeric membrane capable of being disposed within the housing, so as to form a water-resistant seal around the releasable mechanically engageable features; and
wherein the housing is adapted to house an IR transmitting device.

36. A locating badge, comprising:
a housing, wherein at least a portion of the housing is transparent to IR radiation, and at least a portion of the housing is transparent to visible light, and wherein the housing comprises at least a first member and a second member, whereby said housing is capable of being opened to access the interior and re-closed via releasable mechanical engagement along at least a portion of the perimeter of at least one of the housing members;
an elastomeric membrane disposed within the housing, so as to form a water-resistant seal around the releasable mechanical engagement; and
a transmitting device situated inside the housing, capable of transmitting IR signals through the IR-transparent portion of the housing.

37. A locating badge, comprising:
a housing, wherein at least a portion of the housing is transparent to visible light, at least a portion of the housing is transparent to IR radiation; and wherein the housing comprises at least a first member and a second member, whereby said housing is capable of being opened to access the interior and re-closed via a releasable mechanical engagement along at least a portion of the perimeter of at least one of the housing members;
an opaque medium disposed within the housing, wherein the opaque medium is visible through the portion of the housing which is transparent to visible light; and
a transmitting device situated inside the housing, wherein the transmitting device is capable of transmitting electromagnetic waves through the housing, wherein the electromagnetic waves are selected from the group consisting of visible light, IR radiation and any combination thereof.

38. A locating badge, comprising:
a housing, wherein at least a portion of the housing is transparent to visible light, at least a portion of the housing is transparent to IR radiation; and wherein the housing comprises at least a first member and a second member, whereby said housing is capable of being opened to access the interior and re-closed via a releasable mechanical engagement along at least a portion of the perimeter of at least one of the housing members;
an elastomeric membrane disposed within the mechanically engaging portion of the housing, wherein the elastomeric membrane engages with the housing to form a water-resistant seal; and
a transmitting device situated inside the housing, wherein the transmitting device is capable of transmitting IR electromagnetic waves through the housing.
